(19) United States
(12) Patent Application Publication
(10) Pub. No.: US 2026/0101494 A1
(43) Pub. Date: Apr. 9, 2026

(54) MANUFACTURING METHOD OF MEMORY DEVICE

(71) Applicant: NANYA TECHNOLOGY CORPORATION, New Taipei City (TW)

(72) Inventors: Kuan Han CHEN, New Taipei City (TW); Ying-Cheng CHUANG, New Taipei City (TW); Chao-Wen LAY, New Taipei City (TW)

(21) Appl. No.: 18/909,914

(22) Filed: Oct. 8, 2024

(51) Int. Cl. H10B 12/00

(52) U.S. Cl. CPC H10B 12/053

(57) ABSTRACT

A manufacturing method of a memory device, including forming a hard mask layer over a substrate, in which the hard mask layer is made of an oxide-based material, and the hard mask layer has a first width, forming a trench in the substrate through the hard mask layer, performing a first cleaning process to the substrate, in which the first width of the hard mask layer is reduced to a second width after the first cleaning process is complete, forming a first dielectric layer lining the trench, forming a first word line layer in the trench, forming a second word line layer in the trench and over the first word line layer, forming a cap layer in the trench and over the second word line layer, removing the hard mask layer, and forming a gate contact layer over the cap layer.

### BACKGROUND

### Field of Disclosure

The present disclosure relates to a manufacturing method of a memory device.

### Description of Related Art

A typical dynamic random access memory (DRAM) memory cell incorporates a capacitor and a transistor in which the capacitor temporarily store data based on the charged state of the capacitor. A bit line is electrically connected to a source region of the transistor, and a word line is electrically connected to a gate region of the transistor. As technology scaling, the manufacturing process of forming the memory cell faces more challenges. For example, it is more difficult to fill the material in the trench as the trench is narrower.

### SUMMARY

Some embodiments of the present disclosure provide a manufacturing method of a memory device, including forming a hard mask layer over a substrate, in which the hard mask layer is made of an oxide-based material, and the hard mask layer has a first width, forming a trench in the substrate through the hard mask layer, performing a first cleaning process to the substrate, in which the first width of the hard mask layer is reduced to a second width after the first cleaning process is complete, forming a first dielectric layer lining the trench, forming a first word line layer in the trench, forming a second word line layer in the trench and over the first word line layer, forming a cap layer in the trench and over the second word line layer, removing the hard mask layer, and forming a gate contact layer over the cap layer.

In some embodiments, the manufacturing method further includes forming a second dielectric layer over the substrate before forming the hard mask layer, in which the second dielectric layer has a third width before the first cleaning process, and the third width of the second dielectric layer is reduced to a fourth width after the first cleaning process is complete.

In some embodiments, the hard mask layer and the second dielectric layer are both made of oxide-based material.

In some embodiments, the hard mask layer and the second dielectric layer are made of a same material.

In some embodiments, a corner of the hard mask layer becomes rounder after the first cleaning process is complete.

In some embodiments, the manufacturing method further includes after forming the first word line layer, performing a second cleaning process, such that the second width of the hard mask layer is reduced to a third width after the second cleaning process is complete.

In some embodiments, the manufacturing method further includes after performing the second cleaning process, forming a third dielectric layer lining the trench and covering the first word line layer, in which the third dielectric layer is in contact with a sidewall and a bottom surface of the second word line layer.

In some embodiments, a portion of the first dielectric layer is exposed by the first word line layer, and a second cleaning process is performed such that the portion of the first dielectric layer is removed.

In some embodiments, the manufacturing method further includes performing a thermal process to the substrate to form a thermal oxide layer lining the trench after performing the first cleaning process, wherein a portion of the thermal oxide layer is exposed after the second cleaning process is complete.

In some embodiments, the manufacturing method further includes after forming the second word line layer, performing a third cleaning process, such that the third width of the hard mask layer is reduced to a fourth width after the third cleaning process is complete.

Some embodiments of the present disclosure provides a manufacturing method of a memory device including forming a hard mask layer over a substrate, in which the hard mask layer is made of a oxide-based material, and the hard mask layer has a first height, forming a trench in a substrate through the hard mask layer, performing a first cleaning process to the substrate, in which the first height of the hard mask layer is reduced to a second height after the first cleaning process is complete, forming a first dielectric layer lining the trench, forming a first word line layer in the trench, forming a second word line layer in the trench and over the first word line layer, forming a cap layer in the trench and over the second word line layer, and forming a gate contact layer over the cap layer.

In some embodiments, the manufacturing method further includes after forming the first word line layer, performing a second cleaning process, such that the second height of the hard mask layer is reduced to a third height after the second cleaning process is complete.

In some embodiments, forming the first word line layer includes forming a conductive layer overfilling the trench, and etching back the conductive layer until the top surface of the conductive layer is lower than the top surface of the substrate, wherein a portion of the first dielectric layer is exposed after etching back the conductive layer.

In some embodiments, the portion of the first dielectric layer is removed after the second cleaning process is complete.

In some embodiments, a corner of the hard mask layer becomes rounder after the second cleaning process is complete.

In some embodiments, the manufacturing method further includes after performing a second cleaning process, forming a second dielectric layer lining the trench and covering a top surface of the first word line layer.

In some embodiments, forming the second word line layer includes forming a conductive layer overfilling the trench, and etching back the conductive layer until the top surface of the conductive layer is lower than the top surface of the substrate, in which a portion of the second dielectric layer is exposed after etching back the conductive layer.

In some embodiments, the manufacturing method further includes after forming the second word line layer, performing a third cleaning process, such that the third height of the hard mask layer is reduced to a fourth height after the third cleaning process is complete.

In some embodiments, the portion of the second dielectric layer is removed after the third cleaning process is complete.

In some embodiments, a corner of the hard mask layer becomes rounder after the third cleaning process is complete.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-12 illustrate cross-section views of forming a memory structure in some embodiments of the present disclosure.

FIG. 13 illustrates a circuit diagram of the memory device in some embodiments of the present disclosure.

### DETAILED DESCRIPTION

Some embodiments of the present disclosure are related to a method of forming a memory structure. Specifically, the word line layer in the memory layer of the present disclosure is formed with fewer voids to achieve a better performance of the memory structure.

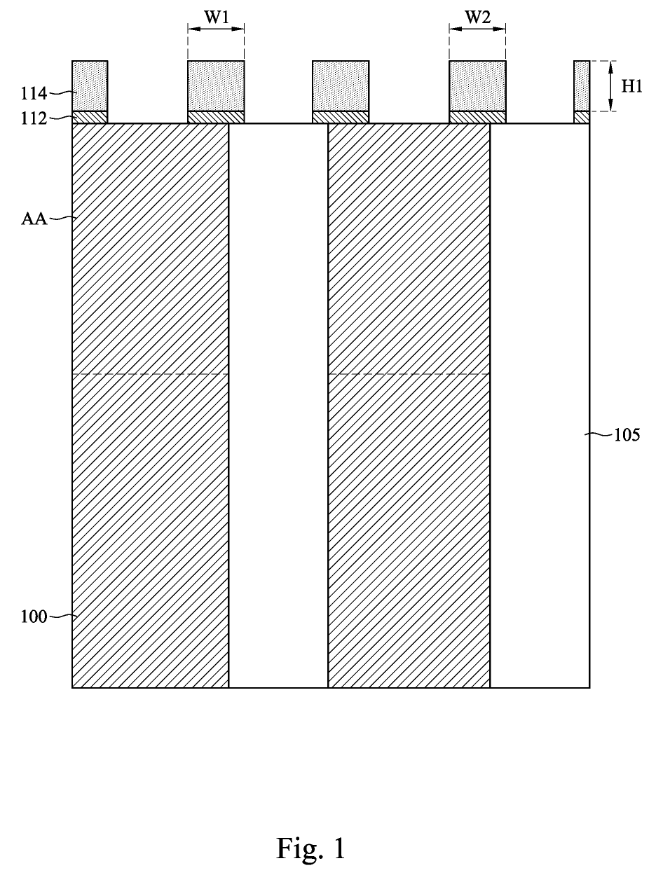

FIGS. 1-12 illustrate cross-section views of forming a memory structure in some embodiments of the present disclosure. Referring to FIG. 1, a substrate 100 is provided, and isolation structures 105 are formed in the substrate 100 to define active regions AA in the substrate 100. The active regions AA are protrusion portions of the substrate 100. The active regions AA and the substrate 100 excluded from the active regions AA may have different conductivity type. In some embodiments, if the active regions AA are n-type region, the substrate 100 excluded from the active regions AA are p-type region. If the active regions AA are n-type region, the substrate 100 excluded from the active regions AA are p-type region. In some embodiments, the substrate 100 is made of semiconductor, such as silicon. In some embodiments, the isolation structures 105 are made of silicon oxide, silicon nitride, or the like.

Subsequently, a dielectric layer 112 and a hard mask layer 114 are formed over the substrate 100 and the isolation structures 105. The dielectric layer 112 and the hard mask layer 114 exposes a portion of the substrate 100 and the isolation structures 105. The dielectric layer 112 and the hard mask layer 114 may be made of an oxide-based material. The dielectric layer 112 and the hard mask layer 114 may be made of same material, such as silicon oxide. The hard mask layer 114 has a first height H1, and the hard mask layer 114 has a width W1. The dielectric layer 112 has a width W2. In some embodiments, the composition of the dielectric layer 112 and the hard mask layer 114 may be different. For example, the oxide content of the dielectric layer 112 and the hard mask layer 114 may be different.

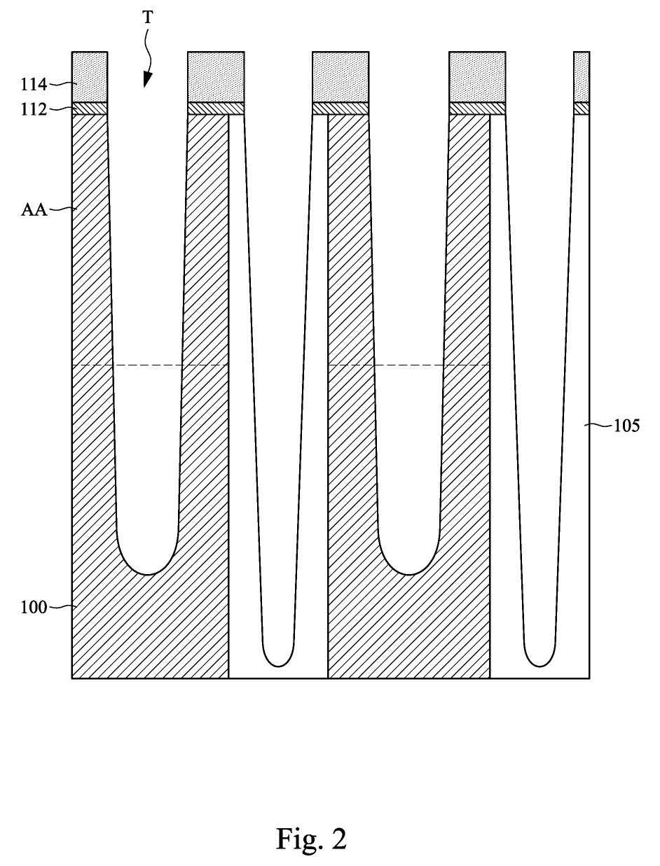

Referring to FIG. 2, trenches T are formed in the substrate 100 and the isolation structures 105 through the dielectric layer 112 and the hard mask layer 114. The trenches T may be formed by performing an etching process to etch the substrate 100 and the isolation structures 105 through the dielectric layer 112 and the hard mask layer 114. In some embodiments, the trenches T may be formed by performing a dry etching process.

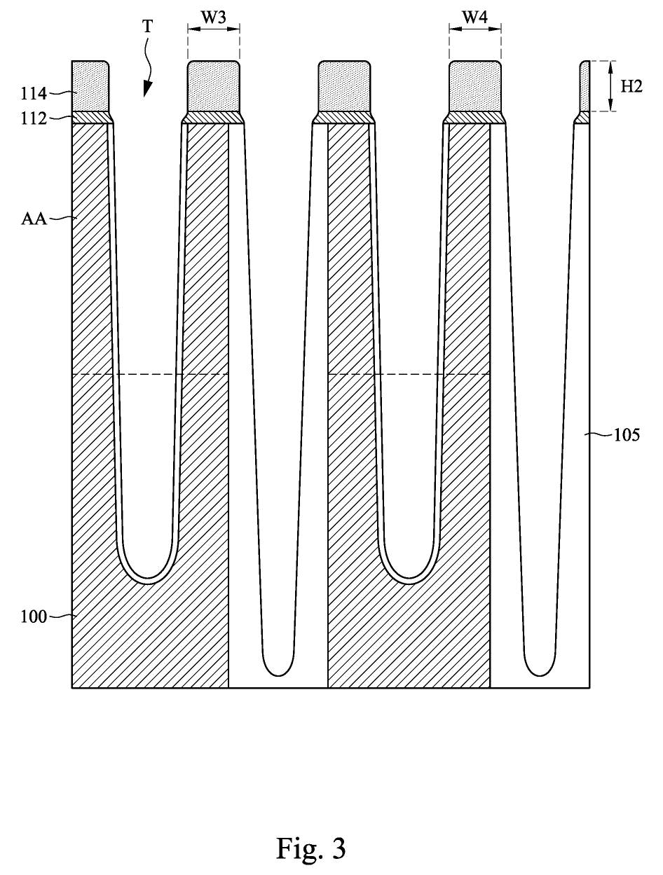

Referring to FIG. 3, a first cleaning process is performed to the substrate 100 to remove the by-products formed at previous stage. For example, the by-products may be native oxide on the surface of the substrate 100 formed at the exposed surface of the substrate 100. Since the dielectric layer 112 and the hard mask layer 114 are also made of oxide, the first cleaning process also partially etches the dielectric layer 112 and the hard mask layer 114. For example, the width W1 of the hard mask layer 114 is reduced to a width W3 after the first cleaning process is complete. The height H1 of the hard mask layer 114 is reduced to a height H2 after the first cleaning process is complete. The corner of the hard mask layer 114 becomes rounder after the first cleaning process is complete. The width W2 of the dielectric layer 112 is reduced to a width W4 after the first cleaning process is complete. In some embodiments, the first cleaning process is performed by using ammonia and hydrogen peroxide mixture (APM), sulfuric acid and hydrogen peroxide mixture (SPM) or other suitable solution as an etchant.

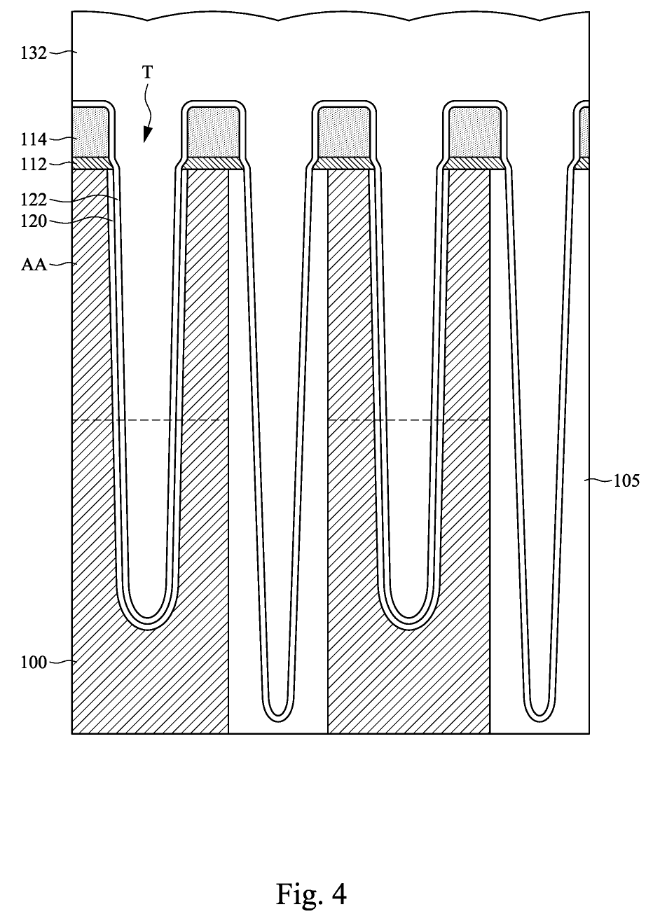

Referring to FIG. 4, a thermal process is performed to the substrate 100 to form a thermal oxide layer 120 conformally on the exposed surface of the substrate 100. Subsequently, a dielectric layer 122 is formed lining the trenches T and over the hard mask layer 114. Since the first cleaning process is performed in FIG. 3, the thermal oxide layer 120 formed conformal to the substrate 100 is smooth and has fewer defects. After forming the thermal oxide layer 120 and the dielectric layer 122, a conductive layer 132 is formed overfilling the trenches T. In some embodiments, the thermal oxide layer 120 may be a silicon oxide layer. The dielectric layer 122 may be made of silicon oxide, silicon nitride, or the like. The conductive layer 132 is made of titanium nitride. Since the height of the hard mask layer 114 and the width of the hard mask layer 114 are reduced after the first cleaning process, the aspect ratio of the trenches T may also be lowered after the first cleaning process is complete. Therefore, it is easier to form the conductive layer 132 having fewer voids in the trenches T.

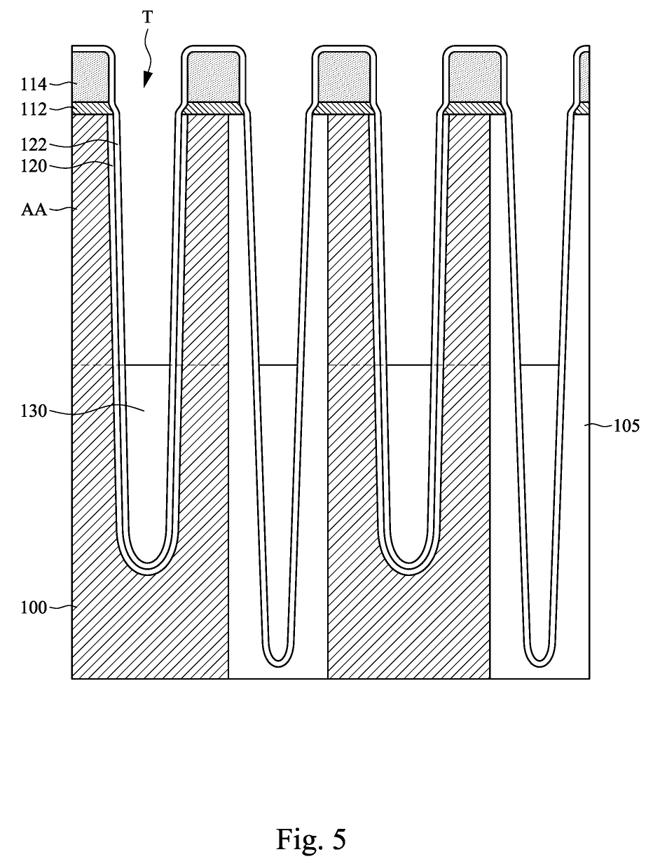

Referring to FIG. 5, the conductive layer 132 is etched back until the top surface of the conductive layer 132 is lower than the top surface of the substrate 100, such that word line layers 130 are formed in the trenches T. A portion of the dielectric layer 122 is exposed after etching back the conductive layer 132. Since the conductive layer 132 having fewer voids is formed in the previous stage, the resulting word line layers 130 have also fewer voids if the hard mask layer 114 is made of silicon oxide.

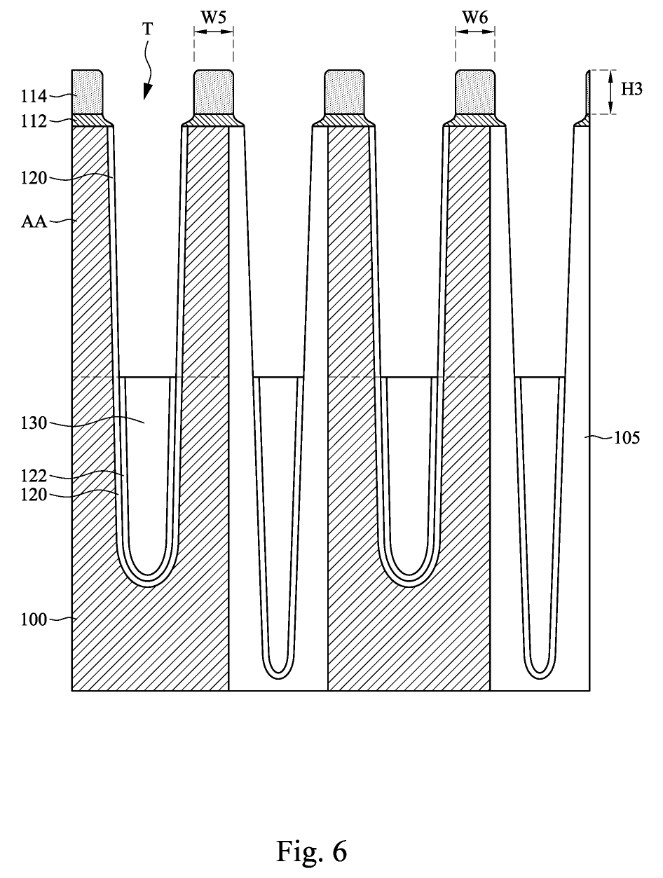

Referring to FIG. 6, a second cleaning process is performed to remove the by-products formed in the previous stage (such as the process to form the word line layer 130). The by-products may be the post-etch residue or the native oxide on the word line layers 130. The second cleaning process also partially etches the dielectric layer 112 and the hard mask layer 114. For example, the width W2 of the hard mask layer 114 is reduced to a width W5 after the second cleaning process is complete. The height H2 of the hard mask layer 114 is reduced to a height H3 after the second cleaning process is complete. The corner of the hard mask layer 114 becomes rounder after the second cleaning process is complete. The width W4 of the dielectric layer 112 is reduced to a width W6 after the second cleaning process is complete. The portion of the dielectric layer 122 exposed by the word line layer 130 is also partially removed after the second cleaning process is complete. In some embodiments, a portion of the dielectric layer 122 is removed, such that the thermal oxide layer 120 is exposed after the second cleaning process is complete. In some embodiments, the second cleaning process is performed by using diluted hydrofluoric acid (DHF) or other suitable solution as an etchant.

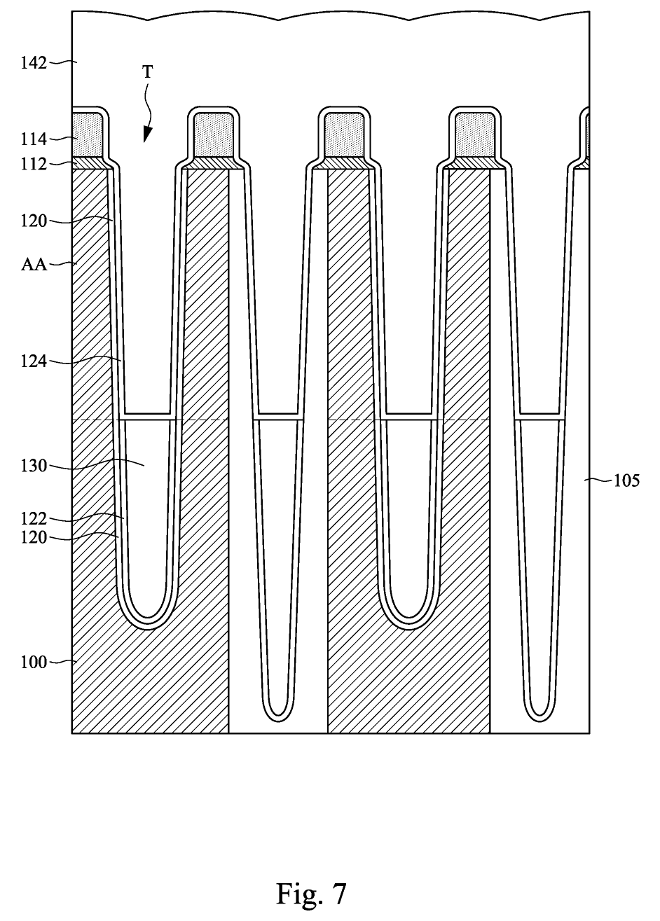

Referring to FIG. 7, a dielectric layer 124 is formed lining the trenches T and covering top surfaces of the word line layers 130. The dielectric layer 124 may be made of silicon oxide, silicon nitride, or the like. Subsequently, a conductive layer 142 is formed overfilling the trenches T and over the word line layer 130. In some embodiments, the conductive layer 142 is made of polysilicon. Since the height of the hard mask layer 114 and the width of the top surface of the hard mask layer 114 are reduced after the second cleaning process, the aspect ratio of the trenches T may also be lowered after the second cleaning process. Therefore, it is easier to form the conductive layer 142 having fewer voids in the trenches T.

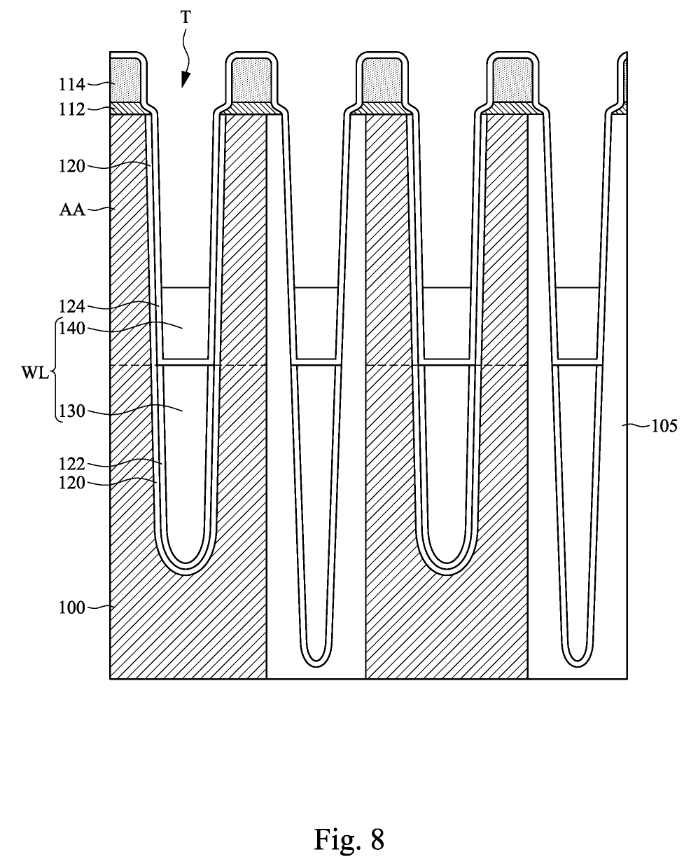

Referring to FIG. 8, the conductive layer 142 is etched back until the top surface of the conductive layer 142 is lower than the top surface of the substrate 100, such that word line layers 140 are formed in the trenches T and over the respective word line layers 130. A portion of the dielectric layer 124 is exposed after etching back the conductive layer 142. The word line layers 130 and the word line layers 140 are separated by the dielectric layer 124, and the dielectric layer 124 is in contact with a sidewall and a bottom surface of the word line layer 140. Since the conductive layer 142 having fewer voids is formed in the previous stage, the resulting word line layers 140 have also fewer voids if the hard mask layer 114 is made of silicon oxide. Each word line layer 130 and its overlying word line layer 140 may be collectively referred to as a word line structure WL.

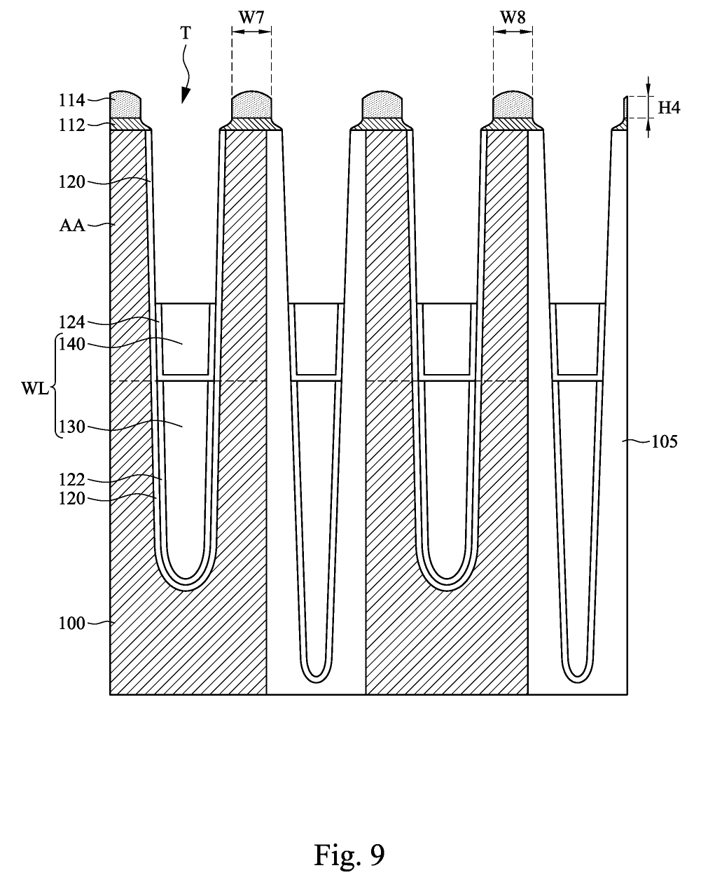

Referring to FIG. 9, a third cleaning process is performed to remove the by-products formed in the previous stage (such as the process to form the word line layer 140). The by-products may be the post-etch residue or the native oxide on the word line layers 140. The third cleaning process also partially etches the dielectric layer 112 and the hard mask layer 114. For example, the width W5 of the hard mask layer 114 is reduced to a width W7 after the third cleaning process is complete. The height H3 of the hard mask layer 114 is reduced to a height H4 after the third cleaning process is complete. The corner of the hard mask layer 114 becomes rounder after the third cleaning process is complete. The width W6 of the dielectric layer 112 is reduced to a width W8 after the third cleaning process is complete. The portion of the dielectric layer 124 exposed by the word line layer 140 is also partially removed after the third cleaning process is complete. In some embodiments, a portion of the dielectric layer 124 is removed, such that the thermal oxide layer 120 is exposed after the second cleaning process. In some embodiments, the third cleaning process is performed by using DHF as an etchant.

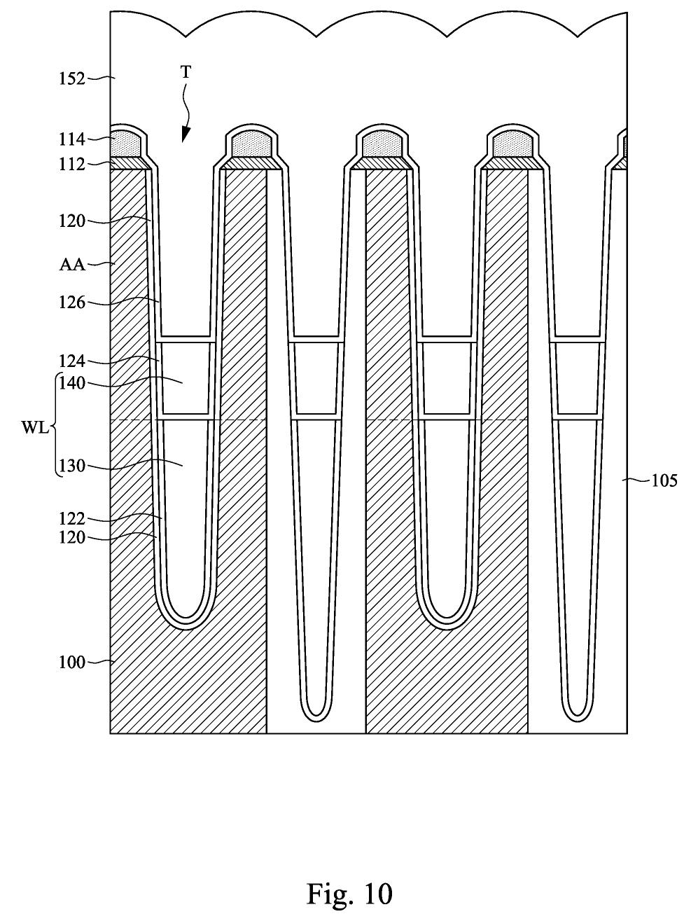

Referring to FIG. 10, a dielectric layer 126 is formed lining the trenches T and covering top surfaces of the word line layers 140 and the hard mask layers 114. The dielectric layer 126 may be made of silicon oxide, silicon nitride, or the like.

Subsequently, a dielectric layer 152 is formed overfilling the trenches T and over the dielectric layer 152. Since the height of the hard mask layer 114 and the width of the top surface of the hard mask layer 114 are reduced after the third cleaning process, the aspect ratio of the trenches T may also be lowered after the third cleaning process. Therefore, it is easier to form the dielectric layer 152 having fewer voids in the trenches T. In some embodiments, the dielectric layer 152 may be silicon nitride layer.

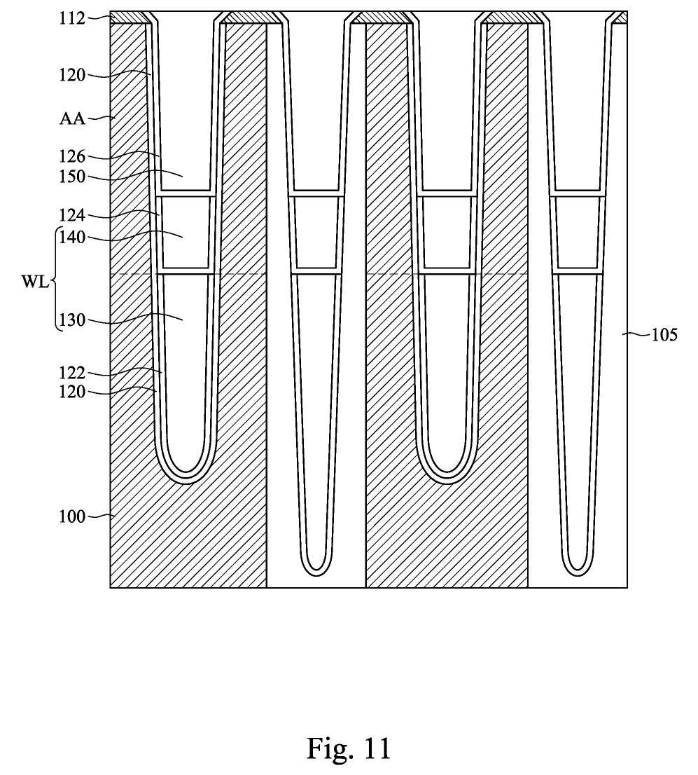

Referring to FIG. 11, a planarization is performed to remove excess material of the dielectric layer 152. In some embodiments, the planarization is performed until the dielectric layers 112 are exposed. . The remaining portions of the dielectric layer 152 in the trenches T are referred to as cap layers 150 Since the dielectric layer 152 having fewer voids is formed in the previous stage, the resulting cap layers 150 have also fewer voids if the hard mask layer 114 is made of silicon oxide.

Discussed in more details, the first cleaning process in FIG. 2, the second cleaning process in FIG. 6, the third cleaning process in FIG. 8 are performed to remove the by-products (e.g., native oxide) resulting from their respective processes, and such cleaning processes may also shrink the hard mask layer 114 and the dielectric layer 112. The width of the top surface of the hard mask layer 114, the height of the hard mask layer 114, and the width of the top surface of the dielectric layer 112 are gradually reduced after the cleaning processes. Therefore, the aspect ratio of the trenches T is reduced, again and again, after the cleaning processes are performed, and will improve the gap-filling capability of the trenches.. The material, such as the word line layers 130, the word line layers 140, the cap layers 150, formed in the trenches T thus have fewer voids. Moreover, the stress of the hard mask layer 114 and the dielectric layer 112 made of silicon oxide is small, so the hard mask layer 114 and the dielectric layer 112 apply less stress to the underlying material, such as the substrate 100. The wiggling issue of the resulting profile of the word line layers 130, the word line layers 140, the cap layers 150 formed in the trenches T is reduced accordingly.

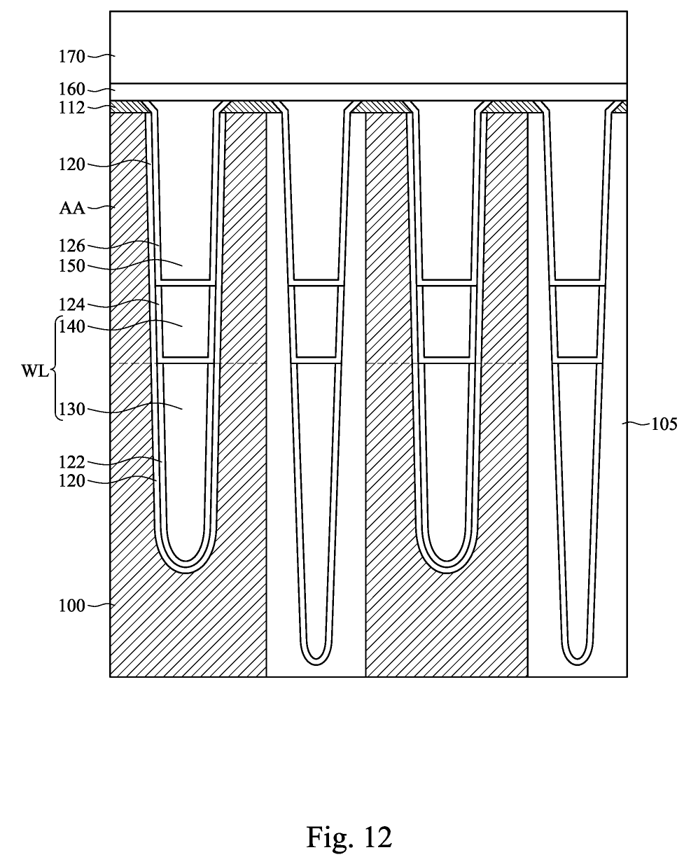

Referring to FIG. 12, a dielectric layer 160 is formed over the cap layers 150 and the dielectric layer 112. Subsequently, a gate contact layer 170 is formed over the cap layers 150 and the dielectric layer 160. In some embodiments, the dielectric layer 152 may be silicon nitride layer. The gate contact layer 170 may be made of conductive material, such as polysilicon.

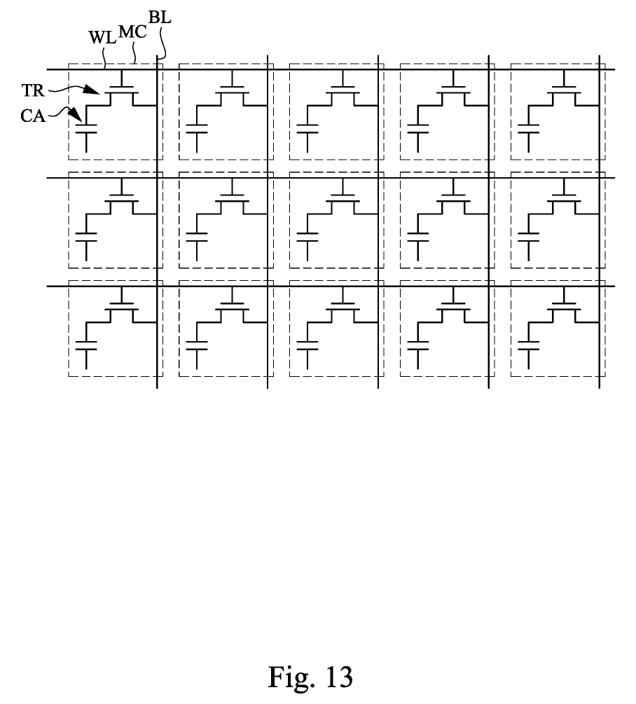

After the gate contact layer 170 is formed, subsequent processes may be performed to form other components, such as bit lines and capacitors to form the memory device. FIG. 13 illustrates a circuit diagram of the memory device in some embodiments of the present disclosure. Referring to FIG. 13, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. A bit line BL is electrically connected to a source/drain region of the transistor TR, and a word line WL is electrically connected to a gate region of the transistor TR. The capacitor CA is electrically connected to the other source/drain region of the respective transistor TR. In some embodiments, the word line structures WL in FIG. 8 may serve as the gate electrode of the transistor TR, the dielectric layer 122, 124 and 126 may serve as the gate dielectric layers of the transistor TR, the substrate 100 may serve as the channel region of the transistor TR, and the active regions AA may serve as source/drain regions of the transistor TR.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
forming a hard mask layer over a substrate, wherein the hard mask layer is made of an oxide-based material, and the hard mask layer has a first width;
forming a trench in the substrate through the hard mask layer;
performing a first cleaning process to the substrate, wherein the first width of the hard mask layer is reduced to a second width after the first cleaning process is complete;
forming a first dielectric layer lining the trench;
forming a first word line layer in the trench;
forming a second word line layer in the trench and over the first word line layer;
forming a cap layer in the trench and over the second word line layer; removing the hard mask layer; and
forming a gate contact layer over the cap layer.

2. The manufacturing method of claim 1, further comprising:
forming a second dielectric layer over the substrate before forming the hard mask layer, wherein the second dielectric layer has a third width before the first cleaning process, and the third width of the second dielectric layer is reduced to a fourth width after the first cleaning process is complete.

3. The manufacturing method of claim 2, wherein the hard mask layer and the second dielectric layer are both made of oxide-based material.

4. The manufacturing method of claim 2, wherein the hard mask layer and the second dielectric layer are made of a same material.

5. The manufacturing method of claim 1, wherein a corner of the hard mask layer becomes rounder after the first cleaning process is complete.

6. The manufacturing method of claim 1, further comprising:
after forming the first word line layer, performing a second cleaning process, such that the second width of the hard mask layer is reduced to a third width after the second cleaning process is complete.

7. The manufacturing method of claim 6, further comprising:
after performing the second cleaning process, forming a third dielectric layer lining the trench and covering the first word line layer, wherein the third dielectric layer is in contact with a sidewall and a bottom surface of the second word line layer.

8. The manufacturing method of claim 6, wherein a portion of the first dielectric layer is exposed by the first word line layer, and wherein the second cleaning process is performed such that the portion of the first dielectric layer is removed.

9. The manufacturing method of claim 8, further comprising:
performing a thermal process to the substrate to form a thermal oxide layer lining the trench after performing the first cleaning process is complete, wherein a portion of the thermal oxide layer is exposed after the second cleaning process is complete.

10. The manufacturing method of claim 6, further comprising:
after forming the second word line layer, performing a third cleaning process, such that the third width of the hard mask layer is reduced to a fourth width after the third cleaning process is complete.

11. A manufacturing method of a memory device, comprising:
forming a hard mask layer over a substrate, wherein the hard mask layer is made of a oxide-based material, and the hard mask layer has a first height;
forming a trench in the substrate through the hard mask layer;
performing a first cleaning process to the substrate, wherein the first height of the hard mask layer is reduced to a second height after the first cleaning process is complete;
forming a first dielectric layer lining the trench;
forming a first word line layer in the trench;
forming a second word line layer in the trench and over the first word line layer;
forming a cap layer in the trench and over the second word line layer; and
forming a gate contact layer over the cap layer.

12. The manufacturing method of claim 11, further comprising:
after forming the first word line layer, performing a second cleaning process, such that the second height of the hard mask layer is reduced to a third height after the second cleaning process is complete.

13. The manufacturing method of claim 12, wherein forming the first word line layer comprises:
forming a conductive layer overfilling the trench; and
etching back the conductive layer until a top surface of the conductive layer is lower than the top surface of the substrate, wherein a portion of the first dielectric layer is exposed after etching back the conductive layer.

14. The manufacturing method of claim 13, wherein the portion of the first dielectric layer is removed after the second cleaning process is complete.

15. The manufacturing method of claim 12, wherein a corner of the hard mask layer becomes rounder after the second cleaning process is complete.

16. The manufacturing method of claim 12, further comprising:
after performing the second cleaning process, forming a second dielectric layer lining the trench and covering a top surface of the first word line layer.

17. The manufacturing method of claim 16, wherein forming the second word line layer comprises:
forming a conductive layer overfilling the trench; and
etching back the conductive layer until the top surface of the conductive layer is lower than the top surface of the substrate, wherein a portion of the second dielectric layer is exposed after etching back the conductive layer.

18. The manufacturing method of claim 17, further comprising:
after forming the second word line layer, performing a third cleaning process, such that the third height of the hard mask layer is reduced to a fourth height after the third cleaning process is complete.

19. The manufacturing method of claim 18, wherein the portion of the second dielectric layer is removed after the third cleaning process is complete.

20. The manufacturing method of claim 18, wherein a corner of the hard mask layer becomes rounder after the third cleaning process is complete.
